(19) United States
(12) Patent Application Publication
(10) Pub. No.: US 2013/0256876 A1
(43) Pub. Date: Oct. 3, 2013

(54) SEMICONDUCTOR PACKAGE

(71) Applicant: SAMSUNG ELECTRONICS CO., LTD., Suwon-si (KR)

(72) Inventors: Ui-hyoung LEE, Hwaseong-City (KR); Moon-gi CHO, Suwon-si (KR); Mi-seok PARK, Hwaseong-si (KR); Sun-hee PARK, Seoul (KR); Hwan-sik LIM, Gunpo-si (KR); Jin-ho CHOI, Yongin-si (KR); Fujisaki ATSUSHI, Seongnam-si (KR)

(73) Assignee: SAMSUNG ELECTRONICS CO., LTD., Suwon-si (KR)

(21) Appl. No.: 13/733,446

(22) Filed: Jan. 3, 2013

(30) Foreign Application Priority Data
Mar. 30, 2012 (KR) 10-2012-0033341

(51) Int. Cl. H01L 23/00

(52) U.S. Cl. CPC H01L 24/14
USPC 257/737

(57) ABSTRACT

A semiconductor package includes a semiconductor chip having a plurality of contact pads on a surface thereof, a plurality of main bumps on the contact pads, respectively. Each of the plurality of main bumps includes a first pillar layer on one of the contact pads and a first solder layer on the first pillar layer, and the first solder layer includes an upper portion having an overhang portion.

### CROSS-REFERENCE TO RELATED APPLICATION

This application claims priority under 35 U.S.C. § 119 to Korean Patent Application No. 10-2012-0033341, filed on Mar. 30, 2012, in the Korean Intellectual Property Office, the contents of which is incorporated herein in its entirety by reference.

### BACKGROUND

As semiconductor devices are miniaturized and have a higher performance, there are demands for semiconductor packages to be highly integrated and thinned. Further, a semiconductor package may be mounted on an external device so as to provide for an electrical connection between a semiconductor chip and a printed circuit board.

### SUMMARY

Embodiments may be realized providing a semiconductor package that includes a semiconductor package having a semiconductor chip including a plurality of contact pads on a surface thereof, and a plurality of main bumps on the contact pads, respectively. Each of the plurality of main bumps includes a first pillar layer on one of the contact pads and a first solder layer on the first pillar layer, and the first solder layer includes an upper portion having an overhang portion.

Side walls of a lower portion of the first solder layer may be substantially vertical, and the upper portion of the first solder layer may have a rounded shape. The overhang portion of the first solder layer may extend in a horizontal direction so as to protrude from side walls of a lower portion of the first solder layer.

Each of the plurality of main bumps may include a first glue layer between the first pillar layer and the first solder layer. The first glue layer may include a material having a melting point that is lower than a melting point of the first solder layer. The first glue layer may include an intermetallic compound and the first solder layer may exclude any intermetallic compounds.

The semiconductor package may include a plurality of dummy bumps on a region of the semiconductor chip around the contact pads. Each of the plurality of dummy bumps may include a second pillar layer on the region of the semiconductor chip around the contact pads and a second solder layer on the second pillar layer, and the second solder layer may include an upper portion thereof having a second overhang portion.

The second overhang portion of the second solder layer may be bigger than the overhang portion of the first solder layer. A bottom surface of the second overhang portion of the second solder layer may be at substantially a same layer level as a bottom surface of the overhang portion of the first solder layer.

Each of the plurality of dummy bumps may include a second glue layer between the second pillar layer and the second solder layer. The semiconductor package may include a seed layer below the first pillar layer.

Embodiments may also be realized by providing a semiconductor package that has a semiconductor chip including a plurality of contact pads on a surface thereof, and a plurality of main bumps on the contact pads, respectively. Each of the plurality of main bumps includes a first pillar layer on one of the contact pads and a first solder layer on the first pillar layer, and the first solder layer has a planar shaped top surface that is arranged at a predetermined angle with respect to side walls of the first solder layer.

The side walls of the first solder layer may be substantially perpendicular to a bottom surface of the semiconductor chip. The first solder layer may have a cylinder shape or a polygonal pillar shape. The first solder layer excludes any intermetallic compounds.

Embodiments may also be realized by providing a semiconductor package that has a semiconductor chip including a plurality of contact pads on a surface thereof, and a plurality of main bumps on the contact pads, respectively. Each of the plurality of main bumps includes a first pillar layer on one of the contact pads and a first solder layer above the first pillar layer, and a middle part of the first solder layer has a greater width than a lower part of the first solder layer and an upper part of the first pillar layer.

The middle part of the first solder layer may include an overhang portion that overhangs the lower part of the first solder layer. The lower part of the first solder layer may be vertically aligned with the upper part of the first pillar layer.

The semiconductor package may include a plurality of dummy bumps on a region of the semiconductor chip around the contact pads. Each of the plurality of dummy bumps may include a second pillar layer and a second solder layer on the second pillar layer, and a middle part of the second solder layer may have a greater width than a lower part of the second solder layer and an upper part of the second pillar layer. The middle part of the second solder layer may be at substantially a same distance from the surface of the semiconductor chip as the middle part of the first solder layer. A lowermost portion of the first pillar layer may be closer to the surface of the semiconductor chip than a lowermost portion of the second pillar layer.

### BRIEF DESCRIPTION OF THE DRAWINGS

Features will become apparent to those of ordinary skill in the art by describing in detail exemplary embodiments with reference to the attached drawings in which:

FIG. 1 illustrates a plan view of a semiconductor package according to an exemplary embodiment;

FIG. 2 illustrates an exemplary cross-sectional view taken along line I-I′ of FIG. 1;

FIG. 3 illustrates a cross-sectional view of a semiconductor package according to an exemplary embodiment;

FIG. 4 illustrates a cross-sectional view of a semiconductor package according to an exemplary embodiment;

FIGS. 5A through 5G illustrate cross-sectional views depicting stages in an exemplary method of manufacturing a semiconductor package;

FIGS. 6A through 6D illustrate cross-sectional views depicting stages in an exemplary method of manufacturing a semiconductor package; and

FIGS. 7A through 7D illustrate cross-sectional views depicting stages in an exemplary method of manufacturing a semiconductor package.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions, e.g., thickness or size of each layer, may be exaggerated for clarity of illustration. Like reference numerals refer to like elements throughout. As used herein, the term “and/or” includes any and all combinations of one or more of the associated listed items.

It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

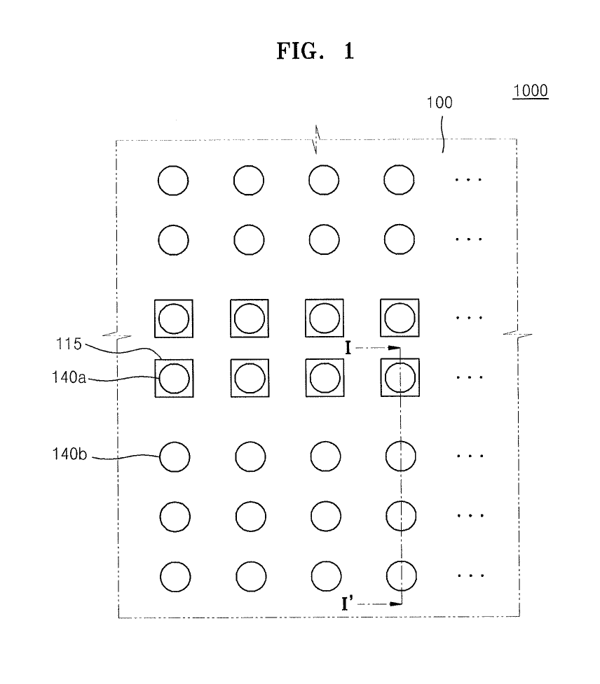

FIG. 1 is a plan view of a semiconductor package 1000 according to an exemplary embodiment.

Referring to FIG. 1, the semiconductor package 1000 includes a semiconductor chip 100, main bumps 140a, and dummy bumps 140b. Each main bump 140a may be formed on a contact pad 115 formed on a surface of the semiconductor chip 100. The main bumps 140a may electrically connect the semiconductor chip 100 to an external device (not shown) such as a printed circuit board. The dummy bumps 140b may be formed on the semiconductor chip 100 around the main bumps 140a. The dummy bumps 140b may support the semiconductor chip 100 when the semiconductor chip 100 is connected to the external device via the main bumps 140a.

The semiconductor chip 100 may include a semiconductor device (not shown). The semiconductor device may be a memory device, such as a dynamic random access memory (DRAM) device, a static random access memory (SRAM) device, a phase-change random access memory (PRAM) device, or a flash memory device, or the semiconductor device may include a non-memory device such as a logic device. For example, the semiconductor device may include therein a transistor, a resistor, and/or a wire. In addition, an element for protecting the semiconductor package 1000 or the semiconductor device, e.g., a passivation layer (not shown), may be formed therein.

The contact pads 115 may be formed on the surface of the semiconductor chip 100. In one embodiment, the contact pads 115 may be arranged on a central area of the semiconductor chip 100, and may be arranged in various forms according to the type and design of the semiconductor device. The contact pads 115 may include a conductive material and may be electrically connected to a conductive region (not shown) of a semiconductor device (not shown) of the semiconductor chip 100. For example, the contact pads 115 may be a redistribution layer.

The main bumps 140a may be formed on the contact pads 115, respectively, of the semiconductor chip 100. For example, each of the main bumps 140a may be formed on one of the contact pads 115 so as to cover at least a portion of a surface of the one of the contact pads 115. In some embodiments, the contact pads 115 are formed on a central area of the semiconductor chip 100, and thus, the main bumps 140a may also be formed on a central area of the semiconductor chip 100. The main bumps 140a may include a conductive material. The main bumps 140a may increase the height of an electrode for connection, e.g., the contact pads 115 for connection with an external device, and facilitate electrical connection.

The dummy bumps 140b may be formed near edges of the semiconductor chip 100. The dummy bumps 140b may be formed in a region where the main bumps 140a are not formed. The dummy bumps 140b may be formed to stably mount the semiconductor chip 100 in an external device (not shown). The dummy bumps 140b may be formed of the same material as that of the main bumps 140a, and may be formed during the forming the main bumps 140a.

The main bumps 140a and the dummy bumps 140b may be arranged in a plurality of rows. For example, as illustrated in FIG. 1, the main bumps 140a may be arranged in two rows on a central area of the semiconductor chip 100, and the dummy bumps 140b may be arranged in a plurality of rows around the main bumps 140a. The main bumps 140a and the dummy bumps 140b may be arranged in a matrix form having rows and columns. Accordingly, a plurality of columns may also be formed that include main bumps 140a and dummy bumps 140b from different rows.

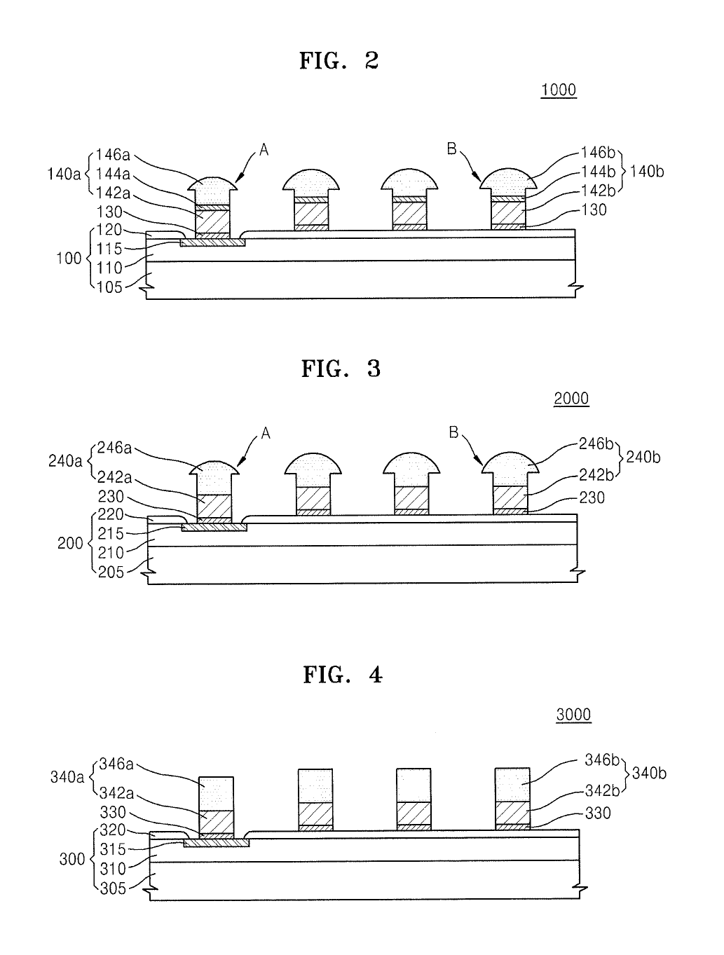

FIG. 2 is a cross-sectional view taken along line I-I′ of FIG. 1, according to an exemplary embodiment.

Referring to FIG. 2, the semiconductor package 1000 includes the semiconductor chip 100, seed layers 130, the main bumps 140a, and the dummy bumps 140b.

The semiconductor chip 100 may include a substrate 105, an insulating interlayer 110, the contact pads 115, and a passivation layer 120.

The substrate 105 may include a semiconductor material such as a Group IV semiconductor, a Group III-V compound semiconductor, or a Group II-VI oxide semiconductor. A semiconductor device (not shown) may be formed on the substrate 105. As described above, the semiconductor device may be a memory device or a non-memory device. A conductive region (not shown) that is connected with the semiconductor device may be further formed on the substrate 105.

The insulating interlayer 110 may be formed on the substrate 105 to cover the semiconductor device and the conductive region. The insulating interlayer 110 may include an insulating material such as silicon oxide, silicon nitride, and/or the like. In some embodiments, the insulating interlayer 110 may include a plurality of insulating layers. Also, the conductive region may have a multi-layered structure, and the plurality of insulating layers may cover the conductive region.

The contact pads 115 may be formed in the insulating interlayer 110 and include a conductive material. For example, the contact pads 115 may be buried in the insulating interlayer 110, e.g., arranged in a trench formed in the insulating interlayer 110. The contact pads 115 may be connected to the conductive region and be electrically connected to the semiconductor device, e.g., through conductive patterns (not shown) extending through the insulating interlayer 110.

The contact pads 115 may function as an input/output (I/O) pad for applying an input/output signal to the semiconductor device. In some embodiments, the contact pads 115 may include at least one selected from aluminum (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), zirconium (Zr), and silicides thereof.

The passivation layer 120 may be formed on the contact pads 115 and the insulating interlayer 110. The passivation layer 120 may cover edges of the contact pads 115, e.g., so as to contact edges of top surfaces of the contact pads 115, and the passivation layer 120 may expose portions, e.g., central portions, of the top surfaces of the contact pads 115. In some embodiments, the passivation layer 120 may include an insulating material such as polyimide, silicon nitride, and/or the like.

In FIG. 2, the top surface of the contact pad 115 and a top surface of the insulating interlayer 110 are formed at the same level, e.g., formed to be substantially coplanar. The passivation layer 120 may be formed on the insulating interlayer 110 to a predetermined thickness. Therefore, an uppermost surface of the passivation layer 120 may be formed at a level higher than that of the top surface of the contact pad 115.

The seed layer 130 may be formed on the portions of the top surfaces of the contact pads 115 that are exposed by the passivation layer 120. Accordingly, the seed layer 130 may be formed within openings of the passivation layer 120.

The main bump 140a may be formed on the contact pad 115. The main bump 140a may include a first pillar layer 142a, a first glue layer 144a, and a first solder layer 146a. The seed layer 130 may be further formed below the main bump 140a. For example, the main bump 140a may extend from, e.g., be grown from, the seed layer 130.

The first pillar layer 142a may be formed on the contact pad 115. The first pillar layer 142a may be formed in the shape of, e.g., a cylinder or a polygonal pillar. The first pillar layer 142a may be formed on the contact pad 115 exposed by the passivation layer 120 at a width that is smaller than that of the contact pad 115. In some embodiments, the first pillar layer 142a may have a thickness of about 3 μm to about 45 μm. The first pillar layer 142a may be an under bump metallurgy (UBM) layer.

The first glue layer 144a may be formed on the first pillar layer 142a in the shape of a cylinder or a polygonal pillar. The first glue layer 144a may have a width that is substantially the same as that of the first pillar layer 142a, e.g., a shape of the first glue layer 144a may be substantially the same as the shape of the first pillar layer 142a. The first glue layer 144a may have a thickness that is smaller than that of the first pillar layer 142a.

The first solder layer 146a may be formed on, e.g., directly on, the first glue layer 144a. A lower portion of the first solder layer 146a may have a cylinder shape or a polygonal pillar shape, and the width of the lower portion of the first solder layer 146a may be substantially the same as that of the first glue layer 144a.

Side walls of the lower portion of the first solder layer 146a may be formed vertical, e.g., so as to be vertically aligned with the side walls of the first pillar layer 142a. An upper portion of the first solder layer 146a may have a round shape. In addition, the upper portion of the first solder layer 146a may have an overhang portion A, e.g., formed around the side walls of the lower portion of the first solder layer 146a. The overhang portion A of the upper portion of the first solder layer 146a may extend in a horizontal direction to protrude away from the side walls of the lower portion of the first solder layer 146a. For example, a middle part of the first solder layer 146a may include the overhang portion A so that the middle part has a greater width than the lower portion of the first solder layer 146a and/or the first pillar layer 142a.

Accordingly, the width of the upper portion of the first solder layer 146a, including the overhang portion A, may be larger than the width of the lower portion of the first solder layer 146a. For example, the width of a lower part of the upper portion of the first solder layer 146a, which lower part includes the overhang portion A, may be larger than the width of the lower portion of the first solder layer 146a. An upper part of the upper portion of the first solder layer 146c may have a decreasing width, e.g., a gradually decreasing width, so that the upper part has a width that is less than the width of the lower portion of the first solder layer 146a. For example, the upper portion of the first solder layer 146a may have a substantially hemispherical shape.

The dummy bumps 140b may be formed on the passivation layer 120 around the contact pads 115. Each dummy bump 140b may include a second pillar layer 142b, a second glue layer 144b, and a second solder layer 146b. The seed layer 130 may be further formed below the dummy bump 140b. The dummy bumps 140b may be formed in regions where the contact pads 115 are not formed so that the seed layer 130 for the dummy bumps 140b is formed on the passivation layer 120.

The second pillar layer 142b may be formed on the passivation layer 120. The second pillar layer 142b may have a cylinder shape or a polygonal pillar shape. The second pillar layer 142b may have a thickness and/or shape that is substantially the same as that of the first pillar layer 142a of the main bump 140a. The second pillar layer 142b may be formed at a level higher than that of the first pillar layer 142a of the main bump 140a so that a lowermost surface of the second pillar layer 142b is further away from the substrate 105 than a lowermost surface of the first pillar layer 142a.

The second glue layer 144b may be formed on the second pillar layer 142b and have a cylinder shape or a polygonal pillar shape. The width of the second glue layer 144b may be substantially the same as that of the second pillar layer 142b. The second glue layer 144b may have a thickness and/or shape that is substantially the same as that of the first glue layer 144a of the main bump 140a. In addition, the second glue layer 144b may be formed at a higher level than the first glue layer 144a of the main bump 140a so that a lowermost surface of the second glue layer 144b is further away from the substrate 105 than a lowermost surface of the first glue layer 144a.

The second solder layer 146b may be formed on, e.g., directly on, the second glue layer 144b. A lower portion of the second solder layer 146b may have a cylinder shape or a polygonal pillar shape, and the width of the lower portion of the second solder layer 146b may be substantially the same as that of the second glue layer 144b.

Side walls of the lower portion of the second solder layer 146b may be formed vertical, e.g., so as to be vertically aligned with the side walls of the second pillar layer 142b. An upper portion of the second solder layer 146b may have a round shape. In addition, the upper portion of the second solder layer 146b may have an overhang portion B, e.g., formed around the side walls of the lower portion of the second solder layer 146b. The overhang portion B may extend in a horizontal direction to protrude away from side walls of the lower portion of the second solder layer 146b. A width of the upper portion of the second solder layer 146b, including the overhang portion B, may be larger than the width of the lower portion of the second solder layer 146b. For example, similar to the upper portion of the first solder layer 146a, the upper portion of the second solder layer 146b may have a substantially hemispherical shape.

The overhang portion B of the second solder layer 146b may be formed at a level similar to that of the overhang portion A of the first solder layer 146a. That is, a bottom surface of the overhang portion B of the second solder layer 146b may be formed at substantially the same level as a bottom surface of the overhang portion A of the first solder layer 146a so that both are arranged at substantially a same distance from the substrate 105. For example, a height of the lower portion of the second solder layer 146b may be less than a height of the lower portion of first solder layer 146a.

According to an exemplary embodiment, the width of the second solder layer 146b, including the overhang portion B, may be larger than that of the first solder layer 146a, including the overhang portion A. A height of the upper portion of the second solder layer 146b may be greater than a height of the upper portion of the first solder layer 146a.

The first pillar layer 142a of the main bump 140a may have substantially the same thickness as that of the second pillar layer 142b of the dummy bump 140b. In addition, the first glue layer 144a of the main bump 140a may have substantially the same thickness as that of the second glue layer 144b of the dummy bump 140b. The first solder layer 146a of the main bump 140a may have substantially the same thickness as that of the second solder layer 146b of the dummy bump 140b. Further, the upper and lower portions of the first solder layer 146a and the second solder layer 146b may have different thickness so that the overhang portion A is horizontally aligned with the overhang portion B so as to both be at substantially a same distance from the substrate 105.

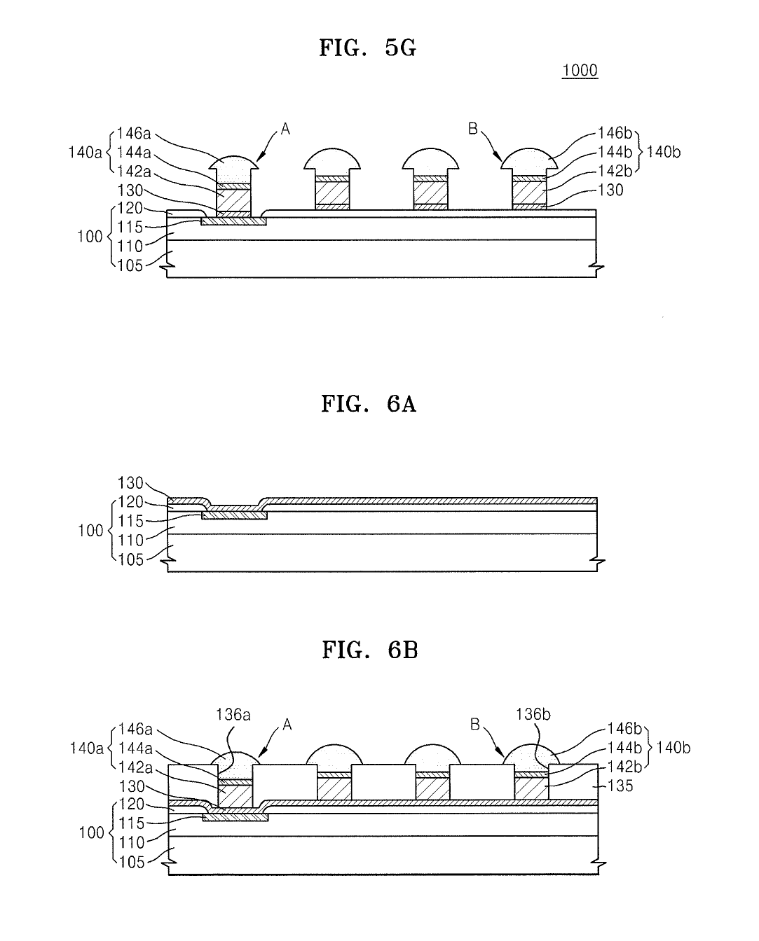

The main bump 140a and the dummy bump 140b may include a conductive material. For example, the first and second pillar layers 142a and 142b may include copper (Cu), nickel (Ni), gold (Au), or a combination thereof. The first and second solder layers 146a and 146b may include at least one metal selected from Cu, Al, Ni, silver (Ag), Au, Pt, tin (Sn), Pb, Ti, chromium (Cr), palladium (Pd), In, Bi, antimony (Sb), Zn, and carbon (C), or an alloy thereof. The first and second solder layers 146a and 146b may not include, e.g., may entirely exclude, an intermetallic compound (IMC) that could be formed by a reflow process performed at a temperature that is higher than a melting point of the first and second solder layers 146a and 146b. This will be described below in more detail with reference to FIGS. 5A through 5G.

The first and second glue layers 144a and 144b may include at least one metal selected from Cu, Al, Ni, Ag, Au, Pt, Sn, Pb, Ti, Cr, Pd, In, Bi, Sb, Zn, and C, or an alloy thereof. The first and second glue layers 144a and 144b may include a material having a melting point that is lower than the melting point of the first and second solder layers 146a and 146b. For example, the first and second glue layers 144a and 144b may include Sn—Zn, Sn—Bi, Sn—Ag, Sn—Zn—Bi, Sn—Ag—Cu, Sn—Bi—Ag—In, or the like. The first and second glue layers 144a and 144b may include an IMC formed by a heat treatment process performed at a temperature that is higher than the melting point of the first and second glue layers 144a and 144b.

According to the semiconductor package 1000, the first and second glue layers 144a and 144b may be disposed respectively between the first and second pillar layers 142a and 142b and the first and second solder layers 146a and 146b. The first and second glue layers 144a and 144b may include an IMC formed at a heat treatment temperature that is lower than a reflow temperature of the first and second solder layers 146a and 146b. A manufacturing process of the semiconductor package 1000 may not include a reflow process, and thus, the possibility of the occurrence of defects such as voids caused by the reflow process may be reduced and/or prevented. Therefore, the semiconductor package 1000 may have an improved reliability.

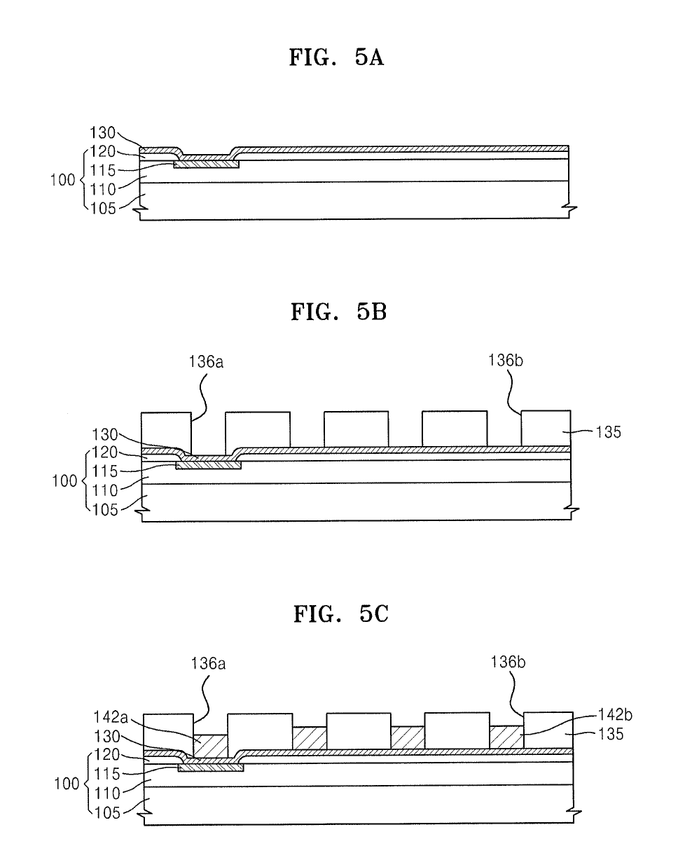

FIG. 3 is a cross-sectional view of a semiconductor package 2000 according to an exemplary embodiment. FIG. 3 may be a cross-sectional view taken along line I-I′ of FIG. 1, according to another exemplary embodiment. The semiconductor package 2000 of FIG. 3 may be substantially similar to the semiconductor package 1000 of FIG. 2, except that the semiconductor package 2000 of FIG. 3 does not include a glue layer. Differences are mainly discussed.

Referring to FIG. 3, the semiconductor package 2000 includes a semiconductor chip 200, seed layers 230, main bumps 240a, and dummy bumps 240b. The semiconductor chip 200 may include a substrate 205, an insulating interlayer 210, contact pads 215, and a passivation layer 220. The insulating interlayer 210 may cover a semiconductor device (not shown) and a conductive region (not shown) that are formed on the substrate 205. The contact pads 215 may be formed on the insulating interlayer 210, e.g., within trenches formed in the insulating interlayer 210. The passivation layer 220 may be formed to cover edges of the contact pads 215 and the insulating interlayer 210.

The main bumps 240a may be formed on the contact pads 215, respectively. The main bump 240a may include a first pillar layer 242a and a first solder layer 246a. Side walls of a lower portion of the first solder layer 246a may be formed substantially vertical, and an upper portion of the first solder layer 246a may have a round shape. The upper portion of the first solder layer 246a may have an overhang portion A. The overhang portion A of the upper portion of the first solder layer 246a may extend in a horizontal direction to protrude away from the side walls of the lower portion of the first solder layer 246a. The seed layer 230 may be further formed below the main bump 240a. The first solder layer 246a may not include an IMC that could potentially be formed during a reflow process performed at a temperature that is higher than a melting point of the first solder layer 246a.

The dummy bumps 240b may be formed on the passivation layer 220 around the contact pads 215. The dummy bump 240b may include a second pillar layer 242b and a second solder layer 246b. An upper portion of the second solder layer 246b may have an overhang portion B that protrudes away from side walls of a lower portion of the second solder layer 246b.

The first pillar layer 242a of the main bump 240a may have substantially the same thickness as that of the second pillar layer 242b of the dummy bump 240b. The first solder layer 246a of the main bump 240a may have substantially the same thickness as that of the second solder layer 246b of the dummy bump 240b. The overhang portion B of the second solder layer 246b may be formed at a similar layer level to the overhang portion A of the first solder layer 246a, e.g., the overhang portion A and the overhang portion B may be horizontally aligned so that both are at a same distance from the substrate 205. The width of the upper portion of the second solder layer 246b, which includes the overhang portion B, may be larger than the width of the upper portion of the first solder layer 246a, which includes the overhang portion A.

A manufacturing process of the semiconductor package 2000 may not include a reflow process, and thus, the possibility of the occurrence of defects such as voids caused by the reflow process may be reduced and/or prevented. Therefore, the semiconductor package 2000 may have an improved reliability.

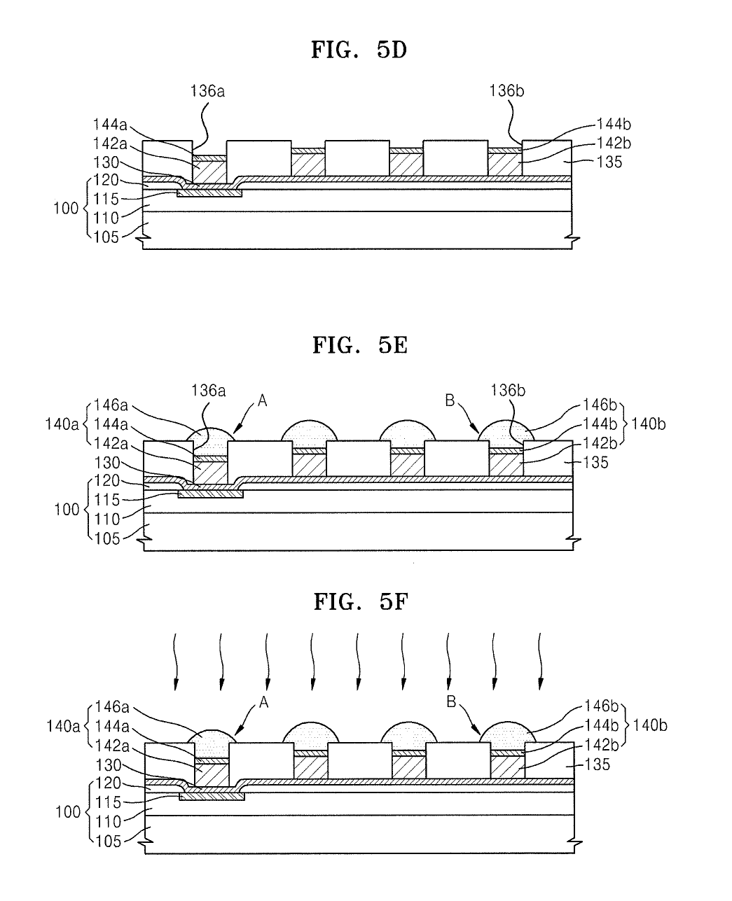

FIG. 4 is a cross-sectional view of a semiconductor package 3000 according to another exemplary embodiment. The semiconductor package 3000 of FIG. 4 has a similar structure to that of the semiconductor package 1000 of FIG. 3, except that the shapes of first and second solder layers 346a and 346b differs from those of the first and second solder layers 246a and 246b. Differences are mainly discussed.

Referring to FIG. 4, the semiconductor package 3000 may include a semiconductor chip 300, seed layers 330, main bumps 340a, and dummy bumps 340b. The semiconductor chip 300 may include a substrate 305, an insulating interlayer 310, contact pads 315, and a passivation layer 320.

The main bumps 340a may be formed on the contact pads 315, respectively. The main bump 340a may include a first pillar layer 342a and the first solder layer 346a.

The first pillar layer 342a may be formed on the contact pad 315 in the form of a cylinder or a polygonal pillar. Side walls of the first pillar layer 342a may be formed substantially perpendicular to a top surface and/or a bottom surface of the semiconductor chip 300. In some embodiments, the first pillar layer 342a may have a thickness of about 3 to about 45 μm.

The first solder layer 346a may be formed on the first pillar layer 342a, e.g., a glue layer (not shown) may be arranged between the first solder layer 346a and the first pillar layer 342a. In some embodiments, side walls of the first solder layer 346a may be formed substantially perpendicular to the top surface and/or the bottom surface of the semiconductor chip 300, e.g., so as to be vertically aligned with the side walls of the first pillar layer 342a. For example, the first solder layer 346a may have a cylinder shape or a polygonal pillar shape. A top surface of the first solder layer 346a may have a predetermined angle with respect to the side walls of the first solder layer 346a and may have a planar shape. For example, the top surface of the first solder layer 346a may be formed substantially in parallel to the top surface of the semiconductor chip 300, e.g., the top surface of the substrate 305. Alternatively, the top surface of the first solder layer 346a may have a rounded shape. Also, an upper portion of the first solder layer 346a may not have an overhang portion that protrudes from the side walls of the first solder layer 346a.

When the first solder layer 346a has a cylinder shape or a polygonal pillar shape, a dimension (e.g., volume) or an amount (e.g., mass) of the first solder layer 346a may be greater than that of a first solder layer having a spherical shape. Therefore, this may facilitate a process of assembling the semiconductor package 3000 on a printed circuit board (not shown) in subsequent processes.

The dummy bumps 340b may be formed on the passivation layer 320 around the contact pads 315. The dummy bump 340b may include a second pillar layer 342b and the second solder layer 346b. The second pillar layer 342b may have a similar shape to that of the first pillar layer 342a, and the second solder layer 346b may have a similar shape to that of the first solder layer 346a. That is, the second pillar layer 342b and the second solder layer 346b may have a cylinder shape or a polygonal pillar shape.

The seed layers 330 may be formed below the main bumps 340a and the dummy bumps 340b.

According to the semiconductor package 3000, the dimension of the first and second solder layers 346a and 346b may be increased, and thus, a subsequent assembling process may be facilitated. In addition, a manufacturing process of the semiconductor package 3000 may not include a reflow process performed at a temperature that is equal to or higher than a melting point of the first and second solder layers 346a and 346b, and thus, the possibility of the occurrence of defects such as voids caused by the reflow process may be reduced and/or prevented. Therefore, the semiconductor package 3000 may have an improved reliability.

FIGS. 5A through 5G are cross-sectional views depicting stages in a method of manufacturing a semiconductor package, according to an exemplary embodiment. The manufacturing method illustrated in FIGS. 5A through 5G may be a manufacturing method of the semiconductor package 1000 of FIG. 2.

Referring to FIG. 5A, the semiconductor chip 100, including the contact pads 115 formed on a surface thereof, may be provided.

First, a semiconductor device (not shown) and a conductive region (not shown) connected to the semiconductor device may be formed on the substrate 105, and then the insulating interlayer 110 that covers the semiconductor device and the conductive region may be formed on the substrate 105. The semiconductor device may be a memory device, such as a DRAM device, an SRAM device, a PRAM device, and a flash memory device, or a non-memory device such as a logic device. The insulating interlayer 110 may be formed by deposition such as chemical vapor deposition (CVD) by using silicon oxide, silicon nitride, and/or the like. In some embodiments, the insulating interlayer 110 may include a plurality of insulating layers.

The contact pads 115 may be formed in the insulating interlayer 110 and may be electrically connected to the conductive region. In some embodiments, the contact pads 115 may include at least one selected from Al, Au, Be, Bi, Co, Hf, In, Mn, Mo, Ni, Pb, Pd, Pt, Rh, Re, Ru, Ta, Te, Ti, W, Zn, Zr, and silicides thereof. In some embodiments, the contact pads 115 may be formed by performing a sputtering process or a thermal evaporation process to form a conductive layer (not shown) and then patterning the conductive layer.

Subsequently, the passivation layer 120 may be formed on the insulating interlayer 110 to expose a portion of each contact pad 115. The passivation layer 120 may be formed so as to cover edges of the contact pads 115 and the insulating interlayer 110. The passivation layer 120 may protect the semiconductor devices. In addition, the passivation layer 120 may serve as a buffer layer that relieves a stress applied from the outside. In some embodiments, the passivation layer 120 may be formed by using an insulating material such as silicon nitride or polyimide.

For example, if the passivation layer 120 is formed of a polyimide-based material such as a photosensitive polyimide (PSPI), the polyimide-based material may be deposited by spin coating, and a patterning process for forming openings may be performed by an exposure process without forming an additional photoresist layer. If the passivation layer 120 is formed of silicon nitride, the passivation layer 120 may be formed by a CVD process and then a photoresist patterning process for exposing top surfaces of the contact pads 115 may be performed.

Next, the seed layer 130 may be formed on the passivation layer 120 and the contact pads 115. In some embodiments, the seed layer 130 may have a double-layered structure. For example, if an electroplating process is performed in subsequent manufacturing processes, an upper seed layer of the seed layer 130 may act as a seed so as to easily grow a plated metal. In addition, a lower seed layer of the seed layer 130 formed on the contact pad 115 may reduce the possibility of and/or prevent materials included in the upper seed layer 130 from diffusing into the insulating interlayer 110.

The seed layer 130 may be formed by using, e.g., Ti, Cu, TiW, or a combination thereof. For example, the seed layer 130 may have a double-layered structure, such as a Ti layer/a Cu layer or a TiW layer/a Cu layer. The seed layer 130 may be formed by a CVD process, a physical vapor deposition (PVD) process, or an atomic layer deposition (ALD) process.

Referring to FIG. 5B, a mask layer 135 having first openings 136a and second openings 136b may be formed on the seed layer 130. The first openings 136a partially expose a top surface of the seed layer 130 formed on the contact pads 115, and the second openings 136b partially expose a top surface of the seed layer 130 formed on the passivation layer 120. In subsequent processes, the main bumps 140a (refer to FIG. 5E) and the dummy bumps 140b (refer to FIG. 5E) may be formed in the first openings 136a and the second openings 136b, respectively.

In some embodiments, the mask layer 135 may be a photoresist layer. For example, the mask layer 135 may be formed by forming by depositing a photoresist layer (not shown) on the seed layer 130 to a predetermined thickness and patterning the photoresist layer by exposing and developing processes. The heights of the main bumps 140a and the dummy bumps 140b may be determined based on the height of the mask layer 135. According to an exemplary embodiment, the height of the mask layer 135 may be about 50 μm.

In some embodiments, the first openings 136a may be formed so as to partially expose the top surface of the seed layer 130 formed on the contact pads 115. The first openings 136a may have a width that is smaller than that of the contact pads 115. In this regard, the top surfaces of the contact pads 115 may be formed at a level lower than that of the top surface of the passivation layer 120, and thus, the depths of the first openings 136a may be a little deeper than those of the second openings 136b.

Referring to FIG. 5C, the first pillar layer 142a may be formed on a portion of the seed layer 130 in the first opening 136a, and the second pillar layer 142b may be formed on a portion of the seed layer 130 in the second opening 136b.

In some embodiments, the first pillar layers 142a and the second pillar layers 142b may be formed using Cu, Ni, Au, or a combination thereof by an electroplating process, an electroless plating process, a CVD process, or a PVD process. For example, the first pillar layers 142a and the second pillar layers 142b may be formed using Cu by an electroplating process. The first and second pillar layers 142a and 142b may enable the main bumps 140a and the dummy bumps 140b (refer to FIG. 5E) to have a fine pitch and may transmit signals between the semiconductor chip 100 and an external device (not shown). The semiconductor chip 100 and the external device may be connected at a given distance by the first and second pillar layers 142a and 142b so that heat generated during the operation of the semiconductor chip 100 may be easily dissipated.

In some embodiments, the first pillar layers 142a and the second pillar layers 142b may be formed by simultaneously filling the first and second openings 136a and 136b by using the seed layer 130 that is partially exposed by the first and second openings 136a and 136b as a seed for growing a metal layer. If the widths of the first and second openings 136a and 136b are substantially the same as each other, the first and second pillar layers 142a and 142b may be formed to have the same thickness. If the widths of the first and second openings 136a and 136b are different, the first and second pillar layers 142a and 142b may be formed to have different thicknesses.

Due to the step difference by the passivation layer 120, a bottom surface of the first pillar layer 142a may be lower than a bottom surface of the second pillar layer 142b, and thus, a top surface of the first pillar layer 142a could be caused to be lower than a top surface of the second pillar layer 142b. If the first and second pillar layers 142a and 142b do not completely fill the first and second openings 136a and 136b, the top surfaces of the first and second pillar layers 142a and 142b could be caused to be lower than the height, e.g., as measured from the lowermost surface of the uppermost surface, of the mask layer 135.

Referring to FIG. 5D, the first glue layer 144a and the second glue layer 144b may be formed on the first pillar layer 142a and the second pillar layer 142b, respectively. The first glue layers 144a and the second glue layers 144b may be formed in the first openings 136a and the second openings 136b, respectively, to a predetermined thickness. Top surfaces of the first and second glue layers 144a and 144b may be lower than the uppermost surface of the mask layer 135. Side walls of upper portions of the first and second openings 136a and 136b may still be exposed after forming the first glue layers 144a and the second glue layers 144b.

The first and second glue layers 144a and 144b may, e.g., prevent corrosion or oxidization of the first and second pillar layers 142a and 142b. The first and second glue layers 144a and 144b may facilitate an adhesion with the first and second solder layers 146a and 146b, respectively, (refer to FIG. 5E) to be formed in subsequent processes.

In some embodiments, the first and second glue layers 144a and 144b may be formed by an electroplating process, an electroless plating process, a CVD process, or a PVD process. The first and second glue layers 144a and 144b may be formed of at least one metal selected from Cu, Al, Ni, Ag, Au, Pt, Sn, Pb, Ti, Cr, Pd, In, Bi, Sb, Zn, and C, or an alloy thereof. For example, the first and second glue layers 144a and 144b may include Sn—Zn, Sn—Bi, Sn—Ag, Sn—Zn—Bi, Sn—Ag—Cu, Sn—Bi—Ag—In, or the like.

The first and second glue layers 144a and 144b may be formed using a material having a melting point that is lower than a melting point of the first and second solder layers 146a and 146b to be formed in subsequent processes. For example, the first and second glue layers 144a and 144b may be formed using Sn—Bi having a melting point of about 138° C., and the first and second solder layers 146a and 146b may be formed using Sn—Ag having a melting point of about 221° C.

Referring to FIG. 5E, the first solder layers 146a and the second solder layers 146b may be formed to a predetermined thickness on the first glue layers 144a formed in the first openings 136a and the second glue layers 144b formed in the second openings 136b, respectively. Accordingly, the main bumps 140a, which each include the first pillar layer 142a, the first glue layer 144a, and the first solder layer 146a may be formed, and the dummy bumps 140b, which each include the second pillar layer 142b, the second glue layer 144b, and the second solder layer 146b may be formed, may be formed on the substrate 105.

In some embodiments, the first and second solder layers 146a and 146b may be formed so as to fill the exposed side walls of the first and second openings 136a and 136b and protrude from the top surface of the mask layer 135. Lower portions of the first and second solder layers 146a and 146b are formed in the first openings 136a and the second openings 136b, respectively, and upper portions of the first and second solder layers 146a and 146b may be formed so as to extend laterally on the mask layer 135. Accordingly, the upper portions of the first and second solder layers 146a and 146b have an overhang portion A and an overhang portion B, respectively.

The first and second solder layers 146a and 146b may reduce the possibility of and/or prevent corrosion or oxidization of the first and second pillar layers 142a and 142b, and also may connect the semiconductor package 1000 to an external device (not shown).

In some embodiments, the first and second solder layers 146a and 146b may be formed by an electroplating process, an electroless plating process, a CVD process, or a PVD process. The first and second solder layers 146a and 146b may be formed of at least one metal selected from the group of Cu, Al, Ni, Ag, Au, Pt, Sn, Pb, Ti, Cr, Pd, In, Bi, Sb, Zn, and C, or an alloy thereof. For example, the first and second solder layers 146a and 146b may include Sn—Ag, Cu—Ni—Pb, Cu—Ni—Au, Cu—Ni, Ni—Au, or Ni—Ag. As described above, the first and second solder layers 146a and 146b may be formed using a material having a melting point that is higher than a melting point of the first and second glue layers 144a and 144b.

The top surface of the second solder layer 146b may be higher than the top surface of the first solder layer 146b, and the second solder layers 146b may protrude more from the top surface of the mask layer 135 than the first solder layers 146a. When the first and second solder layers 146a and 146b completely fill the first and second openings 136a and 136b, respectively, and then protrude from the top surface of the mask layer 134, the first and second solder layers 146a and 146b may extend laterally on the mask layer 135. For example, the second solder layer 146b may extend laterally on the mask layer 135 more than the first solder layer 146a, and the overhang portion B of the second solder layer 146b may be formed larger than the overhang portion A of the first solder layer 146a.

Referring to FIG. 5F, a heat treatment process may be performed on the substrate 105. The heat treatment process may be performed at a temperature that is equal to or less than a melting point of the first and second solder layers 146a and 146b and that is equal to or higher than a melting point of the first and second glue layers 144a and 144b. According to an exemplary embodiment, the heat treatment process may be performed at a temperature that is less than a melting point of the first and second solder layers 146a and 146b and a reflow process may be avoided.

For example, the heat treatment process may be performed at a temperature ranging from about 150° C. to about 200° C., but the heat treatment temperature is not limited thereto. The first and second glue layers 144a and 144b may be melted and then solidified, thereby forming an IMC. Thus, the first pillar layer 142a and the first solder layer 146a may be effectively attached to each other by the first glue layer 144a, and the second pillar layer 142b and the second solder layer 146b may be effectively attached to each other by the second glue layer 144b. For example, when the first and second glue layers 144a and 144b are formed using Sn—Bi having a melting point of about 138° C. and the first and second solder layers 146a and 146b are formed using Sn—Ag having a melting point of about 221° C., the heat treatment process may be performed at a temperature ranging from about 150° C. to about 200° C.

In some embodiments, the heat treatment process may be performed at an atmospheric pressure in a nitrogen (N₂) atmosphere. The heat treatment process may be performed for a few minutes, e.g., 1 minute to 2 minutes.

According exemplary embodiments, the reflow process is not performed. In general, if a reflow process is performed at a temperature that is higher than the melting point of the first and second solder layers 146a and 146b, the first and second solder layers 146a and 146b are melted and reshaped by a surface tension to a hemisphere shape. When an interval (e.g., pitch) between the main bumps 140a and/or the dummy bumps 140b is small, the first and second solder layers 146a and 146b are melted in the reflow process. Accordingly, a bridge phenomenon may occur between the main bumps 140a and/or the dummy bumps 140b, and voids formed in the first and second solder layers 146a and 146b or the first and second solder layers 146a and 146b may cause a collapse. Accordingly, connection defects in the semiconductor package may occur.

As described above, due to the step difference by the passivation layer 120, a top surface of the dummy bump 140b may be higher than a top surface of the main bump 140a, and the overhang portion B of the second solder layer 146b may be formed larger than the overhang portion A of the first solder layer 146a. If the main bumps 140a and the dummy bumps 140b are subjected to a reflow process, the first and second solder layers 146a and 146b may be melted and reshaped by a surface tension to a sphere or hemisphere shape. Accordingly, due to a difference in the sizes of the overhang portions A and B, a difference between the height of the first solder layer 146a and the height of the second solder layer 146b may be further increased, and a difference between the top surface level of the main bump 140a and the top surface level of the dummy bump 140b may be further increased. In this case, the main bumps 140a may be poorly connected to an external device (not shown) in an assembling process of the semiconductor package.

In contrast, according to exemplary embodiments, a heat treatment process may be performed at a temperature that is equal to or less than a melting point of the first and second solder layers 146a and 146b. For example, the heat treatment process may be performed at a temperature that is less than the melting point of the first and second solder layers 146a and 146b and the reflow process may not be performed. Therefore, the possibility of the above-stated the bridge phenomenon, the formation of voids, collapse, and connection defects, of the first and second solder layers 146a and 146b occurring may be reduced and/or prevented.

Referring to FIG. 5G, the mask layer 135 may be removed. For example, the mask layer 135 may be removed by a dry etching process or a wet etching process. For example, if the mask layer 135 is a photoresist layer, the mask layer 135 may be removed by a stripping process such as ashing or washing.

After the mask layer 135 is removed, a structure in which the main bumps 140a and the dummy bumps 140b are formed on the seed layer 130 may be obtained. The main bumps 140a may have a different height from that of the dummy bumps 140b, from the top surface of the semiconductor chip 100 and/or a top surface of the substrate 105.

Next, a portion of the seed layer 130, except for the portions of the seed layer 130 formed below the main bumps 140a and the dummy bumps 140b, may be removed by a dry etching process, e.g., a reactive ion etching (RIE) process. If the overhang portion A of the first solder layer 146a of the main bump 140a and the overhang portion B of the second solder layer 146b of the dummy bump 140b are formed large, the portion of the seed layer 130, except for the portions of the seed layer 130 formed below the main bumps 140a and the dummy bumps 140b, may be removed by a tilted RIE process.

By performing the processes described above, the manufacture of the semiconductor package 1000 may be completed.

According to the manufacturing method of the semiconductor package 1000, the first glue layer 144a and the first solder layer 146 may be sequentially formed on the first pillar layer 142a, and the second glue layer 144b and the second solder layer 146b may be sequentially formed on the second pillar layer 142b. Further, a heat treatment process may performed at a temperature that is equal to or higher than a melting point of the first and second glue layers 144a and 144b and that equal to or is less than a melting point of the first and second solder layers 146a and 146b. For example, the heat treatment process may be performed at a temperature that is less than a melting point of the first and second solder layers 146a and 146b and a reflow process may not be performed. Accordingly, the possibility of generating defects of the first and second solder layers 146a and 146b (e.g., defects such as a bridge phenomenon, the formation of voids, and collapse) may be reduced and/or prevented. Therefore, the semiconductor package 1000 may have an improved reliability.

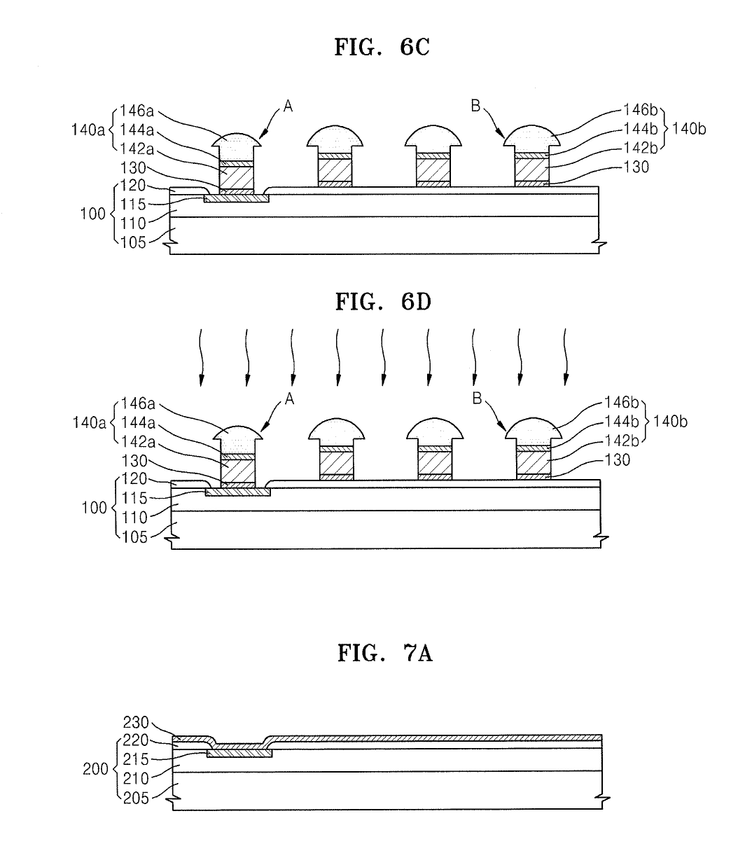

FIGS. 6A through 6D are cross-sectional views depicting stages in a method of manufacturing a semiconductor package, according to another exemplary embodiment. The manufacturing method of FIGS. 6A through 6D may be a manufacturing method of the semiconductor package 1000. The manufacturing method of FIGS. 6A through 6D may be similar to the manufacturing method described above with reference to FIGS. 5A through 5G, except that the manufacturing method of FIGS. 6A through 6D includes a heat treatment process being performed after the mask layer 135 is removed.

Referring to FIG. 6A, the semiconductor chip 100, including the contact pads 115 formed on a surface thereof, may be provided. First, a semiconductor device (not shown) and a conductive region (not shown) connected to the semiconductor device may be formed on the substrate 105, and then the insulating interlayer 110 that covers the semiconductor device and the conductive region may be formed on the substrate 105. The contact pads 115 may be formed in the insulating interlayer 110 and electrically connected to the conductive region. Subsequently, the passivation layer 120 may be formed on the semiconductor chip 100 to expose portions of the contact pads 115. The seed layer 130 may be formed on the passivation layer 120 and the contact pads 115.

Referring to FIG. 6B, a mask layer 135 having first openings 136a and second openings 136b may be formed on the seed layer 130. The first pillar layer 142a may be formed on a portion of the seed layer 130 in the first opening 136a, and the second pillar layer 142b may be formed on a portion of the seed layer 130 in the second opening 136b. The first glue layer 144a and the second glue layer 144b are formed on the first pillar layer 142a and the second pillar layer 142b, respectively. The first solder layer 146a may be formed on the first glue layer 144a to a predetermined thickness in the first opening 136a, and the second solder layer 146b may be formed on the second glue layer 144b to a predetermined thickness in the second opening 136b.

The first and second solder layers 146a and 146b may be formed so as to fill exposed side surfaces of the first and second openings 136a and 136b, respectively, and to protrude from the top surface of the mask layer 135. The first and second solder layers 146a and 146b formed on upper portions of the first and second openings 136a and 136b have an overhang portion A and an overhang portion B, respectively.

Referring to FIG. 6C, the mask layer 135 may be removed. After the mask layer 135 is removed, a structure in which the main bumps 140a are formed on the seed layer 130 and the dummy bumps 140b are formed on the seed layer 130 may be obtained. Subsequently, a portion of the seed layer 130, except for the portions of the seed layer 130 formed below the main bumps 140a and the dummy bumps 140b, may be removed.

Referring to FIG. 6D, a heat treatment process may be performed on the substrate 105. The heat treatment process may be performed at a temperature that is equal to or less than a melting point of the first and second solder layers 146a and 146b and that is equal to or higher than a melting point of the first and second glue layers 144a and 144b. For example, the heat treatment process may be performed at a temperature ranging from about 150° C. to about 200° C., but the heat treatment temperature is not limited thereto. The heat treatment process may be performed at a temperature less than the melting point of the first and second solder layers 146a and 146b and a reflow process may be omitted.

During the heat treatment process, the first and second glue layers 144a and 144b may be melted and then solidified, thereby forming an IMC. In this case, the first pillar layer 142a and the first solder layer 146a may be effectively attached to each other by the first glue layer 144a, and the second pillar layer 142b and the second solder layer 146b may be effectively attached to each other by the second glue layer 144b. For example, when the first and second glue layers 144a and 144b are formed using Sn—Bi having a melting point of about 138° C. and the first and second solder layers 146a and 146b are formed using Sn—Ag having a melting point of about 221° C., the heat treatment process may be performed at a temperature ranging from about 150° C. to about 200° C.

By performing the above-stated processes, the manufacture of the semiconductor package 1000 may be completed.

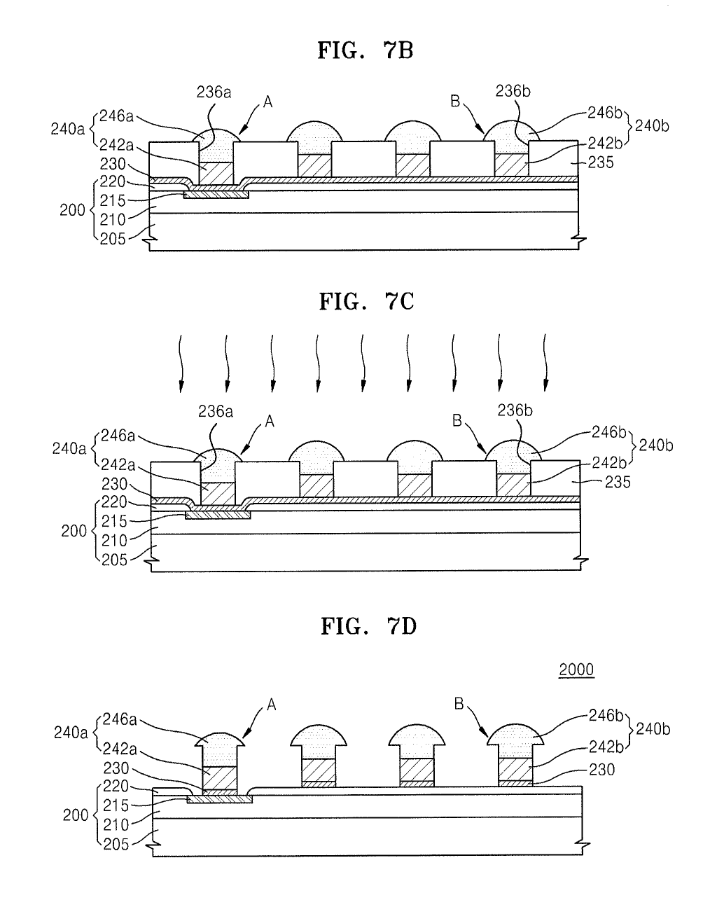

FIGS. 7A through 7D are cross-sectional views depicting stages in a method of manufacturing a semiconductor package, according to another exemplary embodiment. The manufacturing method of FIGS. 7A through 7D may be a manufacturing method of the semiconductor package 2000 of FIG. 3. The manufacturing method of FIGS. 7A through 7D may be similar to the manufacturing method described above with reference to FIGS. 5A through 5G, except that the first and second glue layers 144a and 144b are not formed.

Referring to FIG. 7A, the semiconductor chip 200, including the contact pads 215 formed on a surface thereof, may be provided. First, a semiconductor device (not shown) and a conductive region (not shown) connected to the semiconductor device may be formed on the substrate 205. Then the insulating interlayer 210 that covers the semiconductor device and the conductive region may be formed on the substrate 205. The contact pads 215 may be formed within the insulating interlayer 210 and may be electrically connected to the conductive region. Subsequently, the passivation layer 220 may be formed on the substrate 205 to expose portions of the contact pads 215. The seed layer 230 may be formed on the passivation layer 120 and the contact pads 215.

Referring to FIG. 7B, a mask layer 235 having first openings 236a and second openings 236b may be formed on the seed layer 230. The first pillar layer 242a may be formed on the portion of the seed layer 230 exposed in the first opening 236a, and the second pillar layer 242b may be formed on a portion of the seed layer 230 exposed in the second opening 236b. The first solder layer 246a may be formed on the first pillar layer 242a to a predetermined thickness in the first opening 236a, and the second solder layer 246b may be formed on the second pillar layer 242a to a predetermined thickness in the second opening 236b. The first and second solder layers 246a and 246b may be formed so as to completely fill remaining portions of the first and second openings 236a and 236b. The first and second solder layers 246a and 246b may protrude from a top surface of the mask layer 235, and upper portions of the first and second solder layers 246a and 246b have an overhang portion A and an overhang portion B, respectively.

According to another exemplary embodiment, the first solder layers 246a and the second solder layers 246b may be formed to have a cylinder shape or a polygonal pillar shape when the first and second openings 236a and 236b of the mask layer 235 are not completely filled. For example, side walls of the first solder layer 246a may be formed to correspond to side walls of the first opening 236a and side walls of the second solder layer 246b may be formed to correspond to side walls of the second opening 236b, and thus, the side walls of the first and second solder layers 246a and 246b may be formed substantially perpendicular to a top surface and/or a bottom surface of the semiconductor chip 200 and upper portions of the first and second solder layers 246a and 246b may not have overhang portions. In addition, top surfaces of the first and second solder layers 246a and 246b may be formed at a level lower than that of a top surface of the mask layer 235 to have a planar shape. In this case, the resulting structure may be the semiconductor package 3000 of FIG. 4.

Referring to FIG. 7C, a heat treatment process may be performed on the substrate 205. The heat treatment process may be performed at a temperature that is equal to or less than a melting point of the first and second solder layers 246a and 246b. For example, when the first and second solder layers 246a and 246b are formed using Sn—Ag having a melting point of about 221° C., the heat treatment process may be performed at a temperature ranging from about 150° C. to about 200° C. The heat treatment process may be performed at a temperature less than a melting point of the first and second solder layers 246a and 246b so that the first and second solder layers 246a and 246b are not melted and reshaped, and overhang portions A and B may remain as they are.

Referring to FIG. 7D, the mask layer 235 may be removed. After the mask layer 235 is removed, a structure in which the main bumps 240a are formed on the seed layer 230 and the dummy bumps 240b are formed on the seed layer 230 may be obtained. Subsequently, a portion of the seed layer 230, except for the portions of the seed layer 230 formed below the main bumps 240a and the dummy bumps 240b, may be removed.

With reference to FIG. 7D, a method of removing the mask layer 235 and the portion of the seed layer 230 after the heat treatment process has been described. However, in other embodiments, the mask layer 235 and the portion of the seed layer 230 may be first removed, followed by the heat treatment process.

According to another exemplary embodiment, the heat treatment process may not be performed. For example, if the first and second pillar layers 242a and 242b and the first and second solder layers 246a and 246b are subjected to a reflow process, an IMC may be formed at an interface between the first and second pillar layers 242a and 242b and the first and second solder layers 246a and 246b, and the first and second solder layers 246a and 246b may be reshaped to a sphere shape. When the heat treatment process or the reflow process is not performed, the IMC may be barely formed, height difference between the first and second solder layers 246a and 246b may be avoided, and thus, the possibility of defects in connection between the main bumps 240a and an external device may be reduced and/or prevented.

By performing the above-stated processes, the manufacture of the semiconductor package 2000 may be completed.

By way of summation and review, when a semiconductor package is mounted on an external device a bonding method such as a flip-chip bonding method may be used. In the flip-chip bonding method, a bump may be used for electrical connection between a semiconductor chip and a printed circuit board. Accordingly, in view of reducing the size of a semiconductor devices, a process of forming the bumps having a small size may be improved, e.g., to increase reliability. However, as the size of bumps of a semiconductor package and an interval between the bumps decreases, the connection performance therebetween decreases.

Each of the bumps may include a pillar layer formed on a lower portion thereof and a solder layer formed on an upper portion thereof During the process of forming the electrical connection using the bumps, a reflow process may be performed to melt the solder layer so as to reshape the solder layer into a sphere or hemisphere shape. However, when the reflow process is performed, the solder layer may collapse or voids may be formed in the solder layer and the voids may pop. In addition, a height difference between a main bump for connection and a dummy bump for support may occur. When the solder layer is reshaped into a sphere by the reflow process, the height difference may further increase. Accordingly, defects of connection may occur because the bumps may be poorly connected to an external device.

In contrast, embodiments relate to a semiconductor package in which a semiconductor chip is connected to an external device by bumps to provide a highly reliable semiconductor device. A glue layer may be formed between a pillar layer and a solder layer. The glue layer may be formed of a material having a melting point that is lower than a melting point of the solder layer. Further, a reflow process may be omitted. In place of the reflow process, a heat treatment process may be performed at a temperature between the melting point of the glue layer and the melting point of the solder layer.

The glue layer may include an intermetallic compound to improve adhesive properties of the solder layer. Further, since the reflow process may not be performed, the possibility of defects caused by the reflow process occurring may be reduced and/or prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a semiconductor chip including a plurality of contact pads on a surface thereof; and
a plurality of main bumps on the contact pads, respectively, each of the plurality of main bumps including a first pillar layer on one of the contact pads and a first solder layer on the first pillar layer, the first solder layer including an upper portion having an overhang portion.

2. The semiconductor package as claimed in claim 1, wherein side walls of a lower portion of the first solder layer are substantially vertical, and the upper portion of the first solder layer has a rounded shape.

3. The semiconductor package as claimed in claim 1, wherein the overhang portion of the first solder layer extends in a horizontal direction so as to protrude from side walls of a lower portion of the first solder layer.

4. The semiconductor package as claimed in claim 1, wherein each of the plurality of main bumps includes a first glue layer between the first pillar layer and the first solder layer.

5. The semiconductor package as claimed in claim 4, wherein the first glue layer includes a material having a melting point that is lower than a melting point of the first solder layer.

6. The semiconductor package as claimed in claim 4, wherein the first glue layer includes an intermetallic compound and the first solder layer excludes any intermetallic compounds.

7. The semiconductor package as claimed in claim 1, further comprising a plurality of dummy bumps on a region of the semiconductor chip around the contact pads,
wherein each of the plurality of dummy bumps includes a second pillar layer on the region of the semiconductor chip around the contact pads and a second solder layer on the second pillar layer, the second solder layer including an upper portion thereof having a second overhang portion.

8. The semiconductor package as claimed in claim 7, wherein the second overhang portion of the second solder layer is bigger than the overhang portion of the first solder layer.

9. The semiconductor package as claimed in claim 7, wherein a bottom surface of the second overhang portion of the second solder layer is at substantially a same layer level as a bottom surface of the overhang portion of the first solder layer.

10. The semiconductor package as claimed in claim 7, wherein each of the plurality of dummy bumps includes a second glue layer between the second pillar layer and the second solder layer.

11. The semiconductor package as claimed in claim 1, further comprising a seed layer below the first pillar layer.

12. A semiconductor package, comprising:
a semiconductor chip including a plurality of contact pads on a surface thereof; and
a plurality of main bumps on the contact pads, respectively, each of the plurality of main bumps including a first pillar layer on one of the contact pads and a first solder layer on the first pillar layer, the first solder layer having a planar shaped top surface that is arranged at a predetermined angle with respect to side walls of the first solder layer.

13. The semiconductor package as claimed in claim 12, wherein the side walls of the first solder layer are substantially perpendicular to a bottom surface of the semiconductor chip.

14. The semiconductor package as claimed in claim 12, wherein the first solder layer has a cylinder shape or a polygonal pillar shape.

15. The semiconductor package as claimed in claim 12, wherein the first solder layer excludes any intermetallic compounds.

16. A semiconductor package, comprising:
a semiconductor chip including a plurality of contact pads on a surface thereof; and
a plurality of main bumps on the contact pads, respectively, each of the plurality of main bumps including a first pillar layer on one of the contact pads and a first solder layer above the first pillar layer, a middle part of the first solder layer having a greater width than a lower part of the first solder layer and an upper part of the first pillar layer.

17. The semiconductor package as claimed in claim 16, wherein the middle part of the first solder layer includes an overhang portion that overhangs the lower part of the first solder layer.

18. The semiconductor package as claimed in claim 16, wherein the lower part of the first solder layer is vertically aligned with the upper part of the first pillar layer.

19. The semiconductor package as claimed in claim 16, further comprising a plurality of dummy bumps on a region of the semiconductor chip around the contact pads, wherein:
each of the plurality of dummy bumps includes a second pillar layer and a second solder layer on the second pillar layer, a middle part of the second solder layer having a greater width than a lower part of the second solder layer and an upper part of the second pillar layer, and
the middle part of the second solder layer being at substantially a same distance from the surface of the semiconductor chip as the middle part of the first solder layer.

20. The semiconductor package as claimed in claim 19, wherein a lowermost portion of the first pillar layer is closer to the surface of the semiconductor chip than a lowermost portion of the second pillar layer.
